(19) United States
(12) Patent Application Publication
(10) Pub. No.: US 2008/0185520 A1
(43) Pub. Date: Aug. 7, 2008

(54) Photothermal Inspection Camera Having an Offset Adjusting Device

(75) Inventors: Marc Piriou, Chalon Sur Saone (FR); Laurent Legrandjacques, Lynchburg, VA (US)

Correspondence Address: CONNOLLY BOVE LODGE & HUTZ LLP, 1875 EYE STREET, N.W., SUITE 1100, WASHINGTON, DC, 20036, US

(73) Assignee: AREVA NP, Place de la Coupole (FR)

(21) Appl. No.: 11/912,923

(22) PCT Filed: Mar. 27, 2006
(86) PCT No.: PCT/FR2006/000663

§ 371 Date: Mar. 31, 2008

(30) Foreign Application Priority Data
Apr. 28, 2005 (FR) 0504332

(51) Int. Cl. H01L 25/00

(52) U.S. Cl. 250/332

(57) ABSTRACT

This photothermal examination camera (16) comprises:
a system (22) for shaping a laser beam (4), which includes a device (40) for elongating the cross section of the beam in order to form, on a surface of a part (1) to be examined, an elongate heating zone along a direction;
a matrix (8) of infrared detectors for detecting infrared radiation emitted by a detection zone on the surface (1a) of the part (1) relative to the heating zone; and
a signal processing unit (46) for processing the signals delivered by the infrared detectors in order to construct a thermographic image of the surface (1a) of the part (1) by scanning the surface (1a) with the heating zone.

The camera includes a system for mechanically adjusting an offset between the elongate heating zone and the detection zone.

Application to the non-destructive inspection of parts.

The present invention relates to a photothermal examination camera of the type that comprises:

a system for shaping a laser beam, which includes a device for elongating the cross section of the beam in order to form, on a surface of a part to be examined, an elongate heating zone along a direction;

a matrix of infrared detectors for detecting infrared radiation emitted by a detection zone on the surface of the part relative to the heating zone; and

a signal processing unit for processing the signals delivered by the infrared detectors in order to construct a thermographic image of the surface of the part by scanning the surface with the heating zone.

The invention applies in particular to the non-destructive inspection of parts, for detecting flaws, variations in the nature or properties of their material, for instance in thickness of the coating layers, local variations in thermal diffusivity or conductivity on their surfaces, or beneath their surfaces, etc.

The parts on which the examination is carried out may be metal parts, consisting of ferrous materials, for example alloy steels such as stainless steels, or else nonferrous material. They may also be made of composites, ceramics or plastics.

Photothermal examination is based on the diffusion of a thermal perturbation produced by local heating of the part to be examined.

In practice, a photothermal examination camera emitting a laser beam, which is focused onto the surface of the part under examination, in a heating zone, is used.

The infrared radiation emitted by the part in a detection zone adjacent to or coincident with the heating zone is used to measure or evaluate the temperature rise in the detection zone due to the heating in the heating zone.

The separation between the heating zone and the detection zone is generally called the “offset” this offset may be 0, so that the detection zone then coincides with the heating zone.

The infrared radiation, and therefore the temperature rise, may be measured contactlessly using a detector such as an infrared detector.

The infrared radiation or the temperature rise in the detection zone is influenced by the local characteristics of the materials inspected. In particular, the diffusion of the heat between the heating zone and the detection zone, which is the origin of the temperature rise in the detection zone, depends on the flaws in the part under examination, such as cracks, within the heating zone, or the detection zone, or in the vicinity of these two zones.

By scanning the surface of the part under examination with the heating zone and by detecting the radiation emitted by the detection zone, which moves with the heating zone during the scan, it is thus possible to obtain a thermographic image of the surface of the part, this image being representative of the variations in heat diffusion into the part or of the flaws present within the part.

Previously, a point heating zone and a single infrared detector were used for receiving the radiation emitted by the detection zone, which was also a point zone. The offset between the detection zone and the heating zone therefore had to be very finely controlled using mechanical devices. Furthermore, to scan the surface of a part was very lengthy, so that a photothermal examination method could not in practice be used on an industrial scale. To alleviate these drawbacks, FR-2 760 528 (U.S. Pat. No. 6,419,387) proposed a camera of the aforementioned type.

The creation of an elongate heating zone, rather than a heating spot, helps to reduce the scan time. Furthermore, thanks to the matrix of detectors, it is possible to select a row of detectors from which a thermographic image of the examined part will be constructed. This adjustment of the offset by selecting the detectors in the matrix makes it possible to dispense with the fine mechanical adjustment of the prior art.

In this camera, the cross section of the laser beam is elongate, by the use of a slot through which the laser beam passes.

Such a camera proves to be satisfactory and capable of industrial application.

However, it seems desirable to further improve the quality of the image formed and hence the reliability of the examination that a camera of the aforementioned type permits.

For this purpose, the subject of the invention is a photothermal examination camera of the aforementioned type, characterized in that it includes a system for mechanically adjusting an offset between the elongate heating zone and the detection zone.

According to particular embodiments of the invention, the camera may include one or more of the following features, taken in isolation or in any technically possible combination:

the camera includes a case and the mechanical adjustment system includes a device for displacement of the matrix of infrared detectors relative to the case;

the camera includes a case and the mechanical adjustment system includes a device for displacement of the shaping system relative to the case;

the displacement device comprises a linear motor;

the displacement device comprises a linear piezoelectric actuator;

the displacement device comprises a rotary motor and a mechanism for converting a rotary motion into a translational motion—the elongating device is an optical device;

the optical device includes a lens through which the laser beam is intended to pass;

the optical device includes a mirror intended to reflect the laser beam;

the shaping system includes a device for making the power of the laser beam along the heating zone uniform;

the device for making the power uniform is formed by the device for elongating the cross section of the laser beam;

one face of the lens has a profile suitable for making the power of the laser beam along the heating zone uniform;

one reflecting face of the mirror has a profile suitable for making the power of the laser beam along the heating zone uniform;

the device for making the power uniform is a device for forming the line by the movement of the laser beam perpendicular to its direction of propagation;

the device includes an acoustooptic cell;

the device for making the power uniform includes an oscillating mirror;

the device for making the power uniform includes a bundle of optical fibres, the upstream ends of which receive the laser beam and the downstream ends of which are placed along a line in order to create the elongate heating zone;

the camera includes a system for scanning the surface of the part with the heating zone;

the processing unit is capable of adjusting an offset between the heating zone and the detection zone by selecting a row of infrared detectors in the detection matrix;

the processing unit is capable of independently processing the signals delivered by each of the infrared detectors of the matrix;

the camera includes a laser source; and

the camera includes means for connection to a laser source that does not form part of the camera.

The invention will be more clearly understood on reading the following description, given solely by way of example, and with reference to the appended drawings, in which:

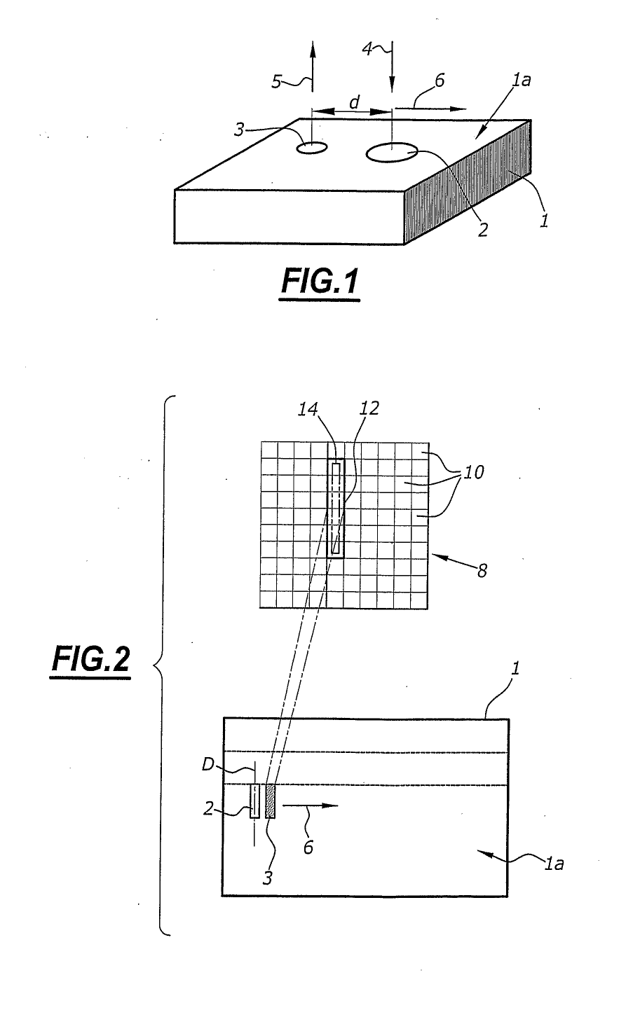

FIG. 1 is a perspective schematic view illustrating the principles of photothermal examination;

FIG. 2 is a diagram illustrating a photothermal examination method carried out using a camera according to the invention;

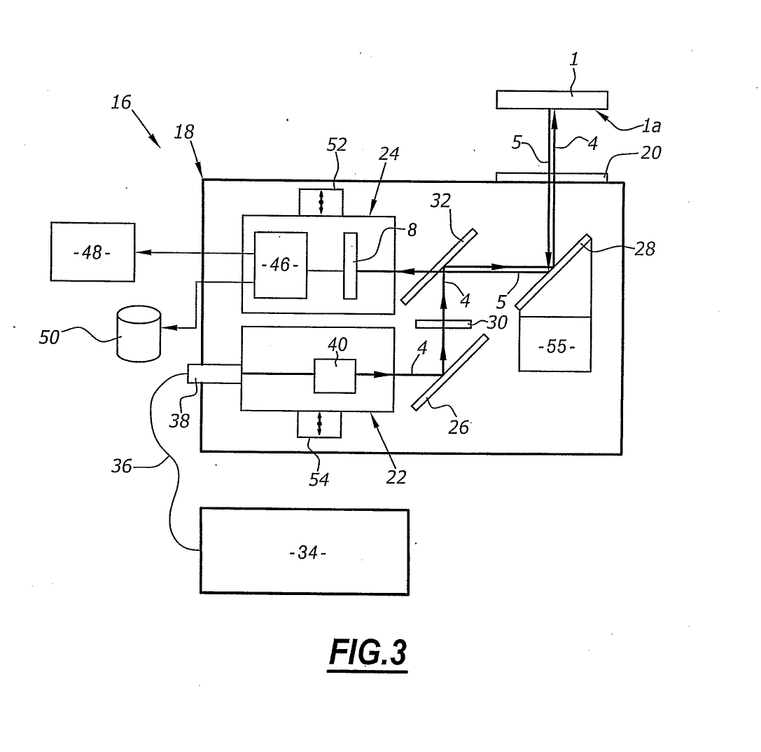

FIG. 3 is a schematic view illustrating a photothermal examination camera according to a first embodiment of the invention;

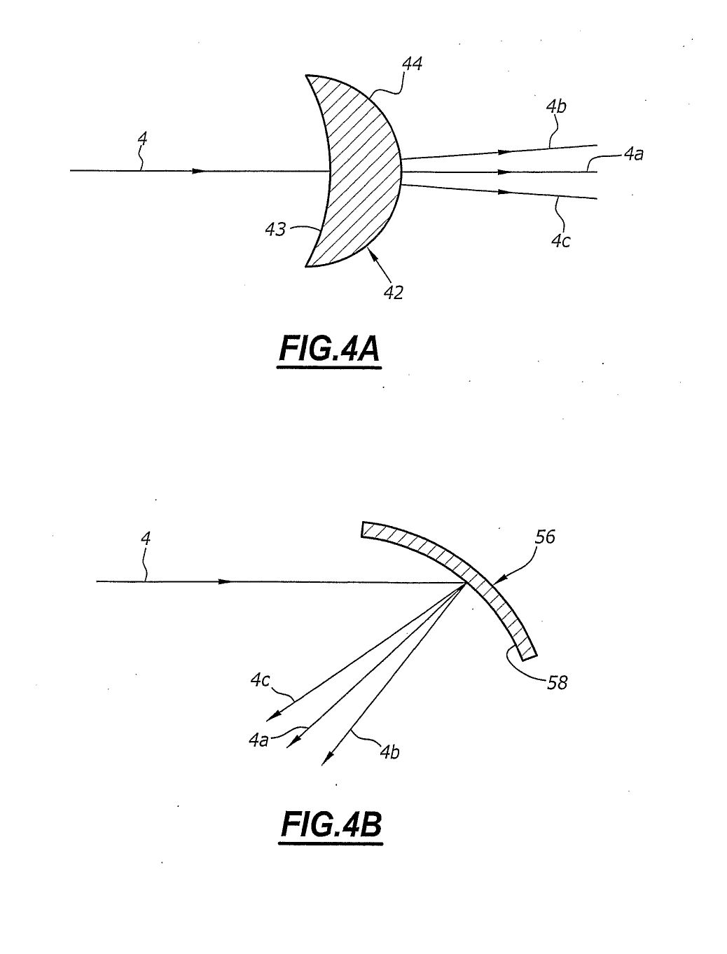

FIG. 4A is a schematic cross section illustrating, in the case of the camera shown in FIG. 3, the device for elongating the cross section of the laser beam;

FIGS. 4B, 5A, 5B and 6 are views similar to FIG. 4A, illustrating alternative embodiments of the device of FIG. 4A;

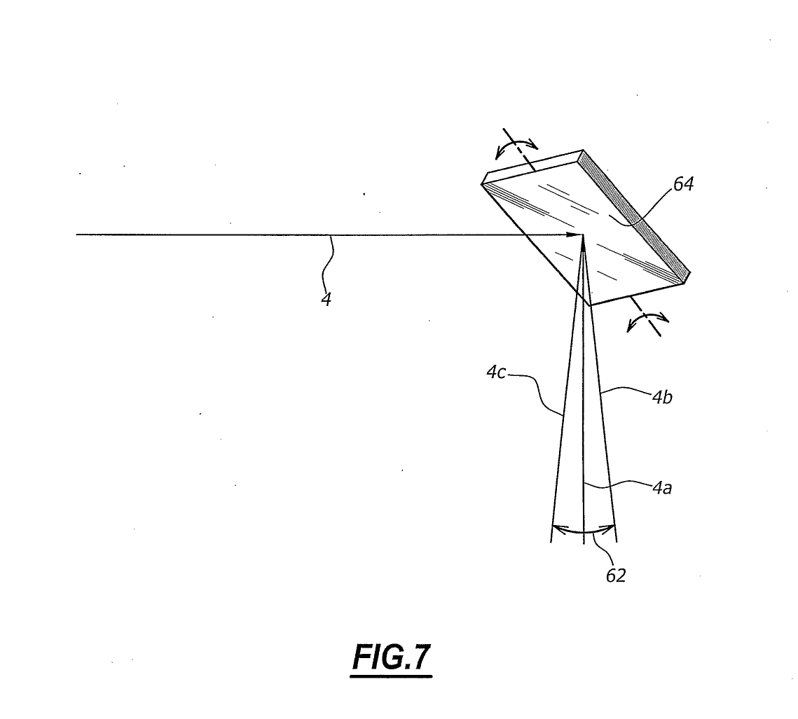

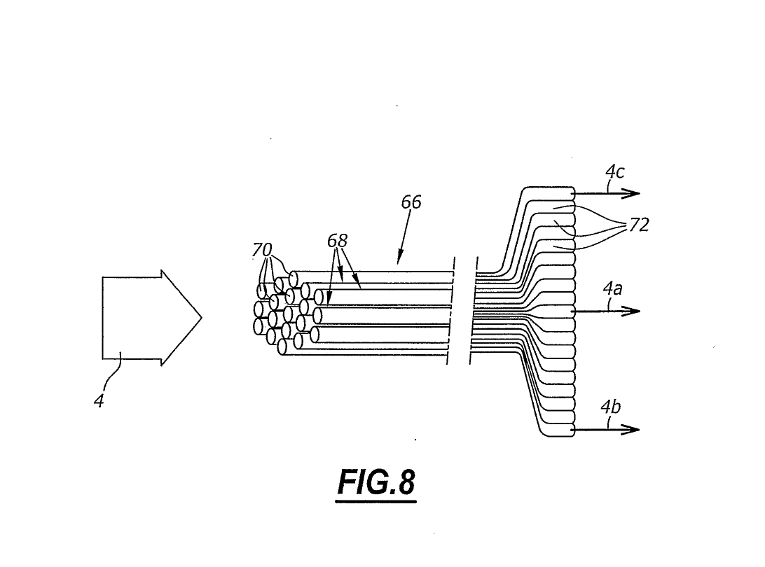

FIGS. 7 and 8 are schematic figures also illustrating two other alternative embodiments of the device of FIG. 4A; and

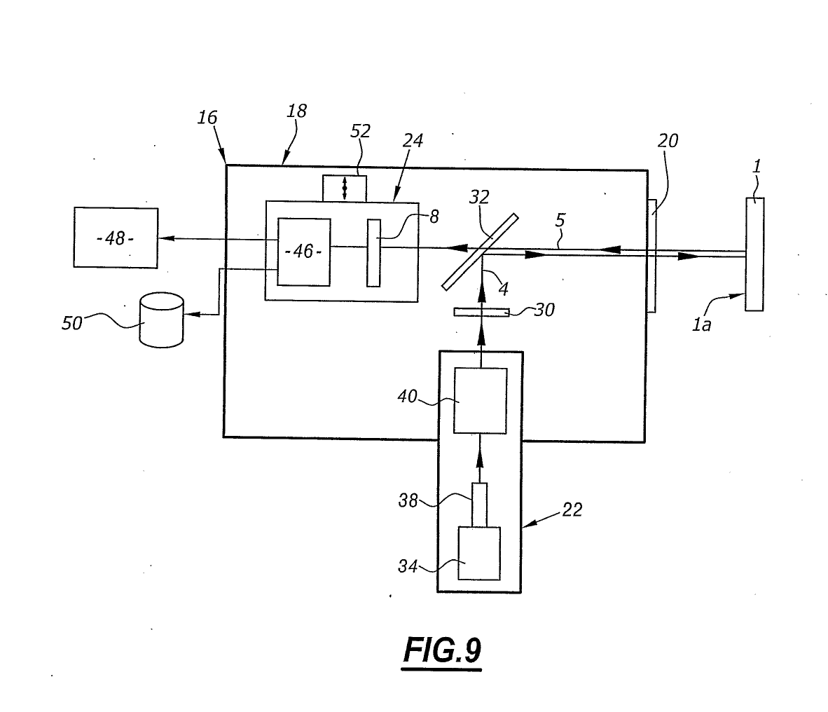

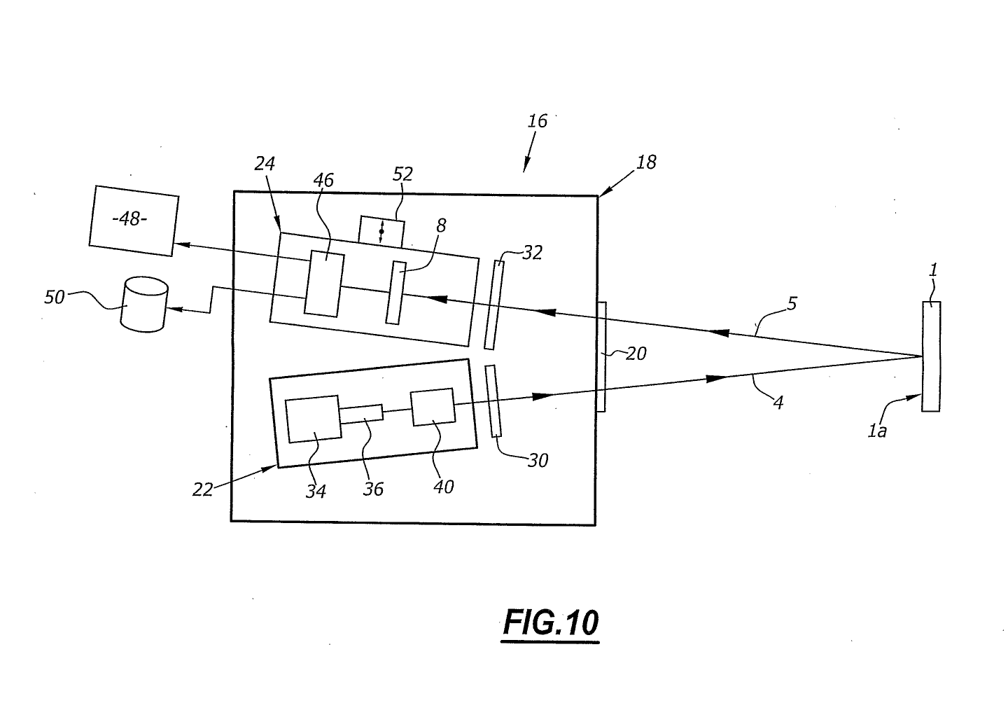

FIGS. 9 and 10 are schematic views illustrating two other embodiments of a camera according to the invention.

As a reminder of the principles of photothermal examination, FIG. 1 shows a part 1 under examination. To examine it, its upper surface 1a is scanned by moving a heating zone 2 and a detection zone 3 synchronously over the surface 1a. The heating zone 2 and the detection zone 3 are offset relative to one another and separated by the distance D called the “offset”. In certain application cases, the offset D is 0 and the zones 2 and 3 are coincident.

The zone 2 is heated by an incident laser beam, portrayed by the arrow 4. The infrared radiation emitted by the detection zone 3 is detected. This radiation is portrayed by the arrow 5 in FIG. 1. The displacement of the zones 2 and 3 is portrayed by the arrow 6.

The displacement 6 may or may not be parallel to the offset d between the heating zone 2 and the detection zone 3. For example, the scan is carried out line by line, the direction of the displacement being reversed for each of the successive liens (“rectangular wave” configuration) or being the same (“comb” configuration).

In FIG. 1, the heating zone 2 is located ahead of the detection zone 3 relative to the direction of displacement 6. However, any other relative position is possible, as described in document FR-2 760 528 (U.S. Pat. No. 6,419,387), the content of which is incorporated here for reference.

FIG. 2 illustrates a photothermal examination method in which the heating zone 2 is an elongate zone along a direction D. More precisely, the zone 2 has the shape of a line, but as a variant it may have another shape, such as an ellipse, etc.

The detection zone 3 has a shape similar to that of the zone 2. It will be noted that, in the example shown in FIG. 2, the detection zone is located ahead of the heating zone 2 relative to the direction of displacement 6.

The use of an elongate heating zone 2 allows the time needed to scan the surface 1a to be reduced, as described in document FR-2 760 528 (U.S. Pat. No. 6,419,387). This feature is also present in the invention.

To detect the emitted radiation 5, a matrix 8 of infrared detectors 10 is used. The matrix 8 generally comprises M rows and N columns. The numbers M and N may vary independently of each other and may for example be between 1 and several hundred, or even more.

As in FR-2 760 528 (U.S. Pat. No. 6,419,387), one row 12 of detectors 10 is selected within the matrix 8 in order to carry-out the examination. FIG. 2 shows the trace 14 of the radiation 5 emitted by the detection zone 3 on the matrix 8 of detectors 10. As may be seen, the selected row 12 comprises in fact the detectors 10 illuminated by the infrared radiation emitted by the detection zone 3.

In the invention, and in FR-2 760 528 (U.S. Pat. No. 6,419,387), by selecting a suitable row 12 of detectors 10, it is possible to adjust the offset d between the heating zone 2 and the detection zone 3.

In practice the emission of the incident laser beam 4 and the detection of the radiation 5 are preferably both performed by the same camera.

FIG. 3 illustrates a photothermal examination camera 16 according to the invention.

This camera 16 mainly comprises:

a case 18 provided with a transparent window 20;

a system 22 for shaping the laser beam 4;

a system 24 for detecting the radiation 5; and

two mirrors 26 and 28, a shutter 30 and a filter plate 32, these elements being interposed in the case 18 between the window 20, the shaping system 22 and the detection system 24, in order to send the shaped laser beam 4 onto the part 1 and for sending radiation 5 onto the detection system 24, as will be seen in detail later.

The shaping system 22 is connected to a laser source 34 via an optical fibre 36. The shaping system 22 comprises a collimator 38 and a device 40 for elongating the cross section of the laser beam 4 emitted by the source 34.

The cross section of the beam 4 is therefore elongate perpendicular to its direction of propagation, so as to form the elongate heating zone 2.

As illustrated in FIG. 4A, the elongating device 40 comprises a lens 42 through which the beam 4 passes. This lens 42 is a divergent cylindrical lens.

This lens 42 makes the bema 4 diverge in the direction along which the elongation has to be produced. This direction is perpendicular to the direction of propagation of the beam 4, as portrayed by the arrows 4a to 4c in FIG. 4A, which illustrate lines of propagation of the beam 4 on exiting the lens 42.

The plane of FIG. 4A contains the elongation direction and the propagation direction of the beam 4.

The plane of FIG. 4A is perpendicular to the plane of FIG. 3.

In the plane of FIG. 4A, the upstream face 43 and the downstream face 44 of the lens 42 have cross sections that are substantially in the form of circular arcs. It will be noted that the lens 42 does not produce an elongation of the beam cross section, and is therefore not divergent, in the plane of FIG. 3.

The detection system 24 comprises the matrix 8 of detectors 10 and a signal processing unit 46 for processing the signals emitted by the detectors 10 of the matrix 8. This unit 46 is capable of independently processing the signals emitted by each of the detectors 10, thereby making it possible in particular to select the row 12 of detectors 10 so as to adjust the offset.

More generally, the unit 46 controls the operation of the entire camera 16.

Conventionally, optical components (not shown) may be placed in the system 24, upstream of the matrix 8 relative to the direction of propagation of the radiation 5, so as to ensure satisfactory operation of the matrix 8.

The unit 46 is capable of constructing a thermographic image on the surface 1a of the part 1 by processing the signals received from the detectors 10 of the selected row 12. The unit 46 may for example be connected to means 48 for displaying the thermographic image and to storage means 50 so as to store the data resulting from the processing. In the example shown, the means 48 and 50 are remote from the camera 16, but as a variant they may form part of the latter.

The plate 32 is a semi-reflecting plate for reflecting the laser beam 4 while still letting through the radiation 5.

More precisely, the plate 32 makes it possible:

to let through the radiation 5, by the use of a substrate having a maximum transmission of the infrared flux in the spectral band corresponding to the temperatures, to which the camera 16 locally brings the inspected part 1; and

to reflect the laser beam 4 by the intermediary of an interference filter (consisting of a stack of layers having different optical indices, deposited on the surface of the substrate) for maximizing the reflectivity of the plate at the wavelength and at the angle of incidence of the beam 4.

To form the substrate of the plate 32, one or more of the following materials may be used:
CaF₂ (calcium fluoride);
MgF₂ (magnesium fluoride);
Al₂O₃ (sapphire);
BaF₂ (barium fluoride);
Ge (germanium);
ZnSe (zinc selenide)

FLIR-ZnS (forward-looking infrared zinc sulphide); multispectral ZnS (zinc sulphide);

MgO (magnesium oxide); and

SrF₂ (strontium fluoride).

The camera 16 includes a device 52 for displacing the detection system 24 relative to the case 18. This displacement system 52 is used to displace the system 24, and therefore the matrix 8 of detectors 10, perpendicular to the radiation 5 upstream of the matrix 8. To do this, the displacement device 52 may for example comprise a linear piezoelectric actuator, a linear motor or a rotary motor combined with a screw/nut mechanism for providing a fine lateral displacement of the detection system 24 perpendicular to the beam 5 in the plane of FIG. 3. Other mechanisms for converting a rotation movement into a translational movement may be envisaged.

Likewise, the camera 16 also includes a device 54 for displacing the shaping system 22. This device 54 has for example a structure similar to that of the device 52 and is used to displace the shaping system 22 perpendicular to the direction of propagation of the beam 4 emanating from the shaping system 22.

The camera 16 also includes a device 55 for displacing the mirror 28, so as to scan the surface 1a with the heating zone 2 and the detection zone 3. This displacement device 55 comprises for example two galvanometers or two motors for scanning the surface 1a in two perpendicular directions.

In the camera 16, the mirror 26 reflects the laser beam 4, elongated by the device 40, onto the shutter 30.

When the shutter 30 is open, it lets through the beam 4, which is reflected by the plate 32 onto the mirror 28 which itself reflects the beam 4 through the window 20 onto the surface 1a.

The radiation 5 passes through the window 20 and is reflected by the mirror 28 onto the plate 32, passing through it before reaching the detection system 24 and illuminating the matrix 8 of the detectors 10.

The unit 46 can then construct, as the scanning proceeds, a thermographic image of the surface 1a, this image being displayed by the display means 48.

Thanks to the use of a device 40 of the optical type, the loss of power of the laser beam is less than in FR-2 760 528 (U.S. Pat. No. 6,419,387) in which a slit is used to elongate the cross section. This makes it possible to reduce the time needed to scan the surface 1, and to use the power of the laser beam 4 more effectively.

Choosing one or more of the aforementioned materials to form the plate 32 improves its performance over time.

This helps to improve the reliability of the examination carried out by the camera 16.

The displacement devices 52 and 54 allow fine mechanical adjustment of the offset d between the heating zone 2 and the detection zone 3. It should be recalled that it may be desirable to conduct the examinations with a zero offset.

This fine adjustment, which may be controlled by the processing unit 46, or manually, is in addition to the possibility of adjustment provided by the choice of row 12 used. This second possibility of mechanically adjusting the offset makes it possible, should the trace 14 of the detection zone 3 be close to or encroach on the boundary of the selected row 12 of detectors, to reposition this trace 14 at the centre of the row 12 chosen.

This third aspect of the invention makes it possible to increase the quality of the thermographic image formed and therefore to increase the precision and the reliability of the examination carried out by the camera 16.

It should be noted that each of these three aspects, namely the use of an optical device 40, the nature of the plate 32 and the mechanical adjustment of the offset, may be used independently of the others.

As regards the first aspect, the device 40 for elongating the cross section may have a different structure from that described above, while still remaining an optical device and not a physical device as in the prior art.

For example, it may comprise several lenses, especially cylindrical lenses.

The term “cylindrical lens” is understood to mean any lens having a different refractive power along the two axes perpendicular to the direction of propagation of the laser beam 4, so as to obtain a beam whose cross section will be greater along one axis than along the other.

Instead of having faces 43 and 44 of circularly arcuate sections, one of these lenses or the lens 42 used, may have a face 44 or several faces with one or more profiles designed to make the power uniform.

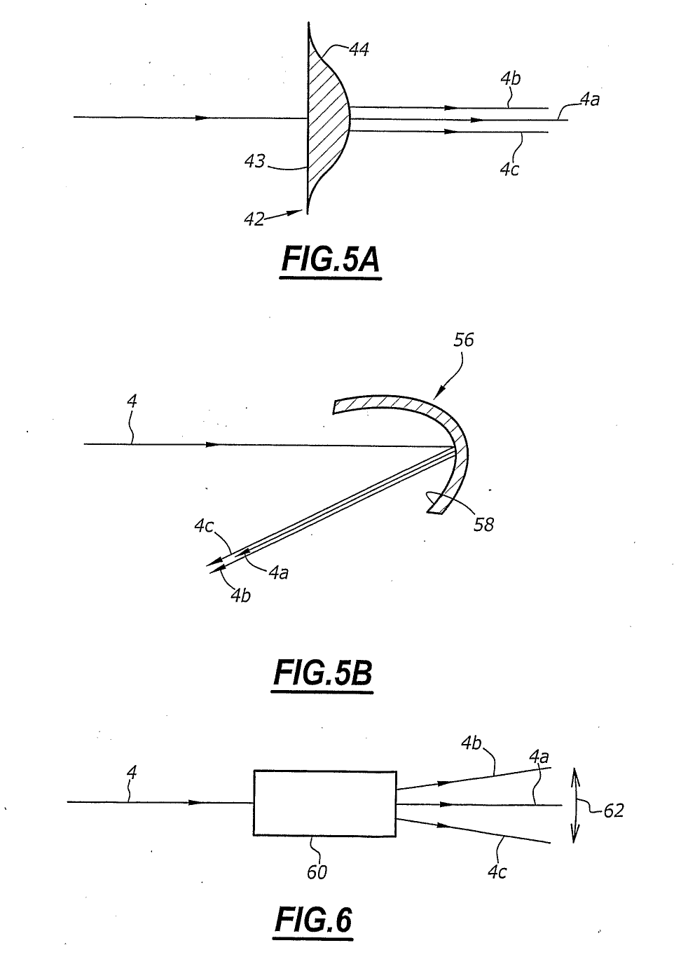

This is illustrated by FIG. 5A in which the downstream face 44 of the lens 42 has a section that differs from a circular arc, this section having a profile designed to increase the uniformity of the power of the laser beam 4 over the length of its section.

The elongating device 40 therefore fulfils two functions, namely that of elongating the cross section of the laser beam 4 and that of making the power of the laser beam 4 uniform over this length.

Since the power distribution along the direction D of the heating zone 2 is relatively uniform thanks to the elongating device 40, the image formed is sharp and the photothermal examination performed by the camera 16 is reliable.

In place of one or more lenses 42, the device 40 may include one or more mirrors which fulfil, by reflection, the functions of elongating the cross section and possibly of making the power uniform. The device 40 may therefore include a mirror 56 having a face 58, which reflects the beam 4, with a circularly arcuate section or a profiled section designed to make the power uniform.

Such mirrors 56 and their reflecting faces 58 are shown in FIGS. 4B and 5B, respectively.

It will be observed that, in the above examples, the elongation of the cross section of the laser beam is effected by increasing this cross section along one dimension. As a variant, this elongation may be achieved by reducing the width of the beam cross section.

Likewise, depending on the device 40 used, the collimator 38 may be omitted.

As a variant, the device 40 may also fulfil the functions of elongating the cross section and possibly of making the power uniform by moving the laser beam 4. In this case, the optical device 40 may comprise, for example, an acoustooptic cell 60. As illustrated in FIG. 6, this acoustooptic cell 60 elongates the cross section of the beam 4 by moving the latter along the direction in which its cross section has to be elongated. This movement is portrayed by the double arrow 62 in FIG. 6.

As a variant, and as illustrated by FIG. 7, the laser beam 4 may be moved by an oscillating mirror 64.

FIG. 8 illustrates yet another variant. The optical device 40 then includes a bundle 66 of optical fibres 68, the upstream ends of which receive the laser beam 4 and the downstream ends 72 of which are aligned so that they produce, as output, a laser beam 4 of elongate cross section.

Yet other variants are conceivable. In particular, the functions of elongating the cross section on the one hand, and of making the power uniform on the other, may be provided by two separate devices.

As regards the mechanical adjustment of the offset, it is unnecessary for the camera 16 to possess both a device 52 for displacing the detection system 24 and a device 54 for displacing the shaping system 22, since it may include only one of these devices.

This is illustrated by FIG. 9, in which the camera 16 includes only a device 52 for displacing the shaping system 24.

The structure of the camera 16 is further simplified in that the laser source 34 has been integrated into the camera 16 and the mirrors 26 and 28 have been omitted.

Furthermore, the camera 16 shown in FIG. 9 does not include an integrated displacement device 55 for scanning the surface 1a.

This scanning is therefore provided by a device for displacing the part 1 of by a device for displacing the camera 16, this device being located outside the latter.

More generally, the mechanical adjustment of the offset d, used in addition to the software adjustment by selection of the row 12, may be carried out by means of devices for displacing one or more of the optical components placed between the shaping system 22, the detection system 24 and the part 1 to be examined. It is therefore not essential to displace the shaping system 22 or the detection system 24.

Yet other embodiments are conceivable. In particular, the beam 4 incident on the part 1 and the emitted infrared beam 5 are not necessarily parallel, but may be inclined relative to each other, as illustrated schematically by FIG. 10 as an example.

In FIG. 10, the plate 32 serves as a filter for protecting the detectors 10 of the matrix 8.

Likewise, it is not essential to use a filter plate.

1. Photothermal examination camera (16), of the type that comprises:
a system (22) for shaping a laser beam (4), which includes a device (40) for elongating the cross section of the beam in order to form, on a surface of a part (1) to be examined, an elongate heating zone (2) along a direction (D);
a matrix (8) of infrared detectors (10) for detecting infrared radiation emitted by a detection zone (3) on the surface (1a) of the part (1) relative to the heating zone (2); and
a signal processing unit (46) for processing the signals delivered by the infrared detectors (10) in order to construct a thermographic image of the surface (1a) of the part (1) by scanning the surface (1a) with the heating zone (2),
wherein it includes a system (52, 54) for mechanically adjusting an offset (d) between the elongate heating zone (2) and the detection zone (3).

2. Camera according to claim 1, wherein it includes a case (18) and in that the mechanical adjustment system includes a device (52) for displacement of the matrix (8) of infrared detectors (10) relative to the case (18).

3. Camera according to claim 1, wherein it includes a case (18) and in that the mechanical adjustment system includes a device (54) for displacement of the shaping system (22) relative to the case (18).

4. Camera according to claim 2, wherein the displacement device (52, 54) comprises a linear motor.

5. Camera according to claim 2, wherein the displacement device (52, 54) comprises a linear piezoelectric actuator.

6. Camera according to claim 2, wherein the displacement device (52, 54) comprises a rotary motor and a mechanism for converting a rotary movement into a translational movement.

7. Camera according to claim 1, wherein the elongating device (40) is an optical device.

8. Camera according to claim 7, wherein the optical device (40) includes a lens (42) through which the laser beam (4) is intended to pass.

9. Camera according to claim 7, wherein the optical device (40) includes a mirror (56) intended to reflect the laser beam (4).

10. Camera according to claim 7, wherein the shaping system (22) includes a device (40) for making the power of the laser beam (4) along the heating zone (2) uniform.

11. Camera according to claim 10, wherein the device for making the power uniform is formed by the device (40) for elongating the cross section of the laser beam.

12. Camera according to claim 8, wherein one face (44) of the lens (42) has a profile suitable for making the power of the laser beam (4) along the heating zone (2) uniform.

13. Camera according to claim 9 wherein one reflecting face (58) of the mirror (56) has a profile suitable for making the power of the laser beam (4) along the heating zone (2) uniform.

14. Camera according to claim 11, wherein the device (40) for making the power uniform is a device for forming the line by the movement of the laser beam (4) perpendicular to its direction of propagation.

15. Camera according to claim 14, wherein the device (40) includes an acoustooptic cell (60).

16. Camera according to claim 14, wherein the device (40) for making the power uniform includes an oscillating mirror (64).

17. Camera according to claim 11, wherein the device (40) for making the power uniform includes a bundle (66) of optical fibres (68), the upstream ends (70) of which receive the laser beam (4) and the downstream ends of which are placed along a line in order to create the elongate heating zone (2).

18. Camera according to claim 1, wherein it includes a system for scanning the surface (11) of the part (1) with the heating zone (2).

19. Camera according to claim 1, wherein the processing unit (46) is capable of adjusting an offset (d) between the heating zone (2) and the detection zone (3) by selecting a row (12) of infrared detectors (10) in the detection matrix (8).

20. Camera according to claim 1, wherein the processing unit (46) is capable of independently treating the signals delivered by each of the infrared detectors (10) of the matrix (8).

21. Camera according to claim 1, wherein it includes a laser source (34).

22. Camera according to claim 1, wherein it includes means (36) for connection to a laser source (34) that does not form part of the camera.
